(19) United States
(12) Patent Application Publication
(10) Pub. No.: US 2008/0260179 A1
(43) Pub. Date: Oct. 23, 2008

(54) Active loudspeaker

(76) Inventor: Jens Kurrat, Berlin (DE)

Correspondence Address: William Koerner, 1006 S. Raven Rd., Shorewood, IL, 60404, US

(21) Appl. No.: 12/000,584

(22) Filed: Dec. 14, 2007

(30) Foreign Application Priority Data
Apr. 19, 2007 (DE) AZ 102007019756.1

(51) Int. Cl. H04R 3/04; H03F 21/00

(52) U.S. Cl. 381/103; 381/120

(57) ABSTRACT

In an active loudspeaker, a bridge rectifier generates an unregulated DC voltage from the AC mains power supply voltage. A self-oscillating pulse modulator generates a pulse-modulated switch signal that is controlling a power switch stage which is switching the unregulated DC voltage. The power-switched signal is low-pass filtered and driving a high-impedance speaker element. The amplifier is compensating fluctuations and noise in the unregulated DC voltage by feeding a reference signal back to the pulse modulator which is derived by voltage-dividing the power-switched signal. The audio volume is regulated by adjusting the voltage divider ratio of the feedback signal. The loudspeaker provides galvanic voltage isolation of the speaker inputs through an audio input stage to comply with safety regulations. This invention eliminates the regulated switched-mode power supply in active loudspeaker applications and thereby reduces cost and weight.

### CROSS REFERENCE TO RELATED APPLICATION

This invention claims priority from German patent application Ser. No. AZ 10 2007 019 756.1 filed on Apr. 19, 2007.

### TECHNICAL FIELD OF INVENTION

This invention relates to an active loudspeaker for audio reproduction, comprising a line voltage rectifier, an input stage, a pulse modulator, a power switch stage, a low-pass filter and a speaker element.

### BACKGROUND OF THE INVENTION

Active loudspeakers are particularly suited for applications requiring fairly high output power, such as subwoofer systems as well as speakers comprising several speaker elements where the audio signal is often separated into several frequency bands prior to amplification and each speaker element is driven by a separate amplifier. In addition, a large variety of music and video appliances provide integrated active speakers, such as TVs, radios or integrated CD player systems.

The audio amplifier of these speakers and appliances is typically powered by a switched-mode power supply. Aside from providing power to the amplifier, such power supply also offers galvanic isolation between the operating voltage and the mains voltage which is a fundamental safety requirement in most countries. Depending on the rated output power of the amplifier, such power supply constitutes a fairly large portion of the overall system cost and system weight. As such, audio system designers have been trying to minimize the size and cost of the power supply while at the same time offering high rated audio output power. Switched-mode power supplies offer higher efficiency and lower weight than linear supplies. However, there still is significant energy loss present thus lowering the overall system energy efficiency and requiring heat sinking.

To improve efficiency of the amplifier, many audio devices use a pulse modulation (“digital”) switching class D power amplifier. Compared to conventional linear class A, AB and B amplifiers, such amplifiers offer improved power efficiency while at the same time offering acceptable to good audio quality compared to linear amplifiers. For achieving high output power, such switching amplifiers usually are configured in full-bridge mode, i.e. each speaker terminal is driven by a dedicated switch stage thereby raising system cost compared to single ended amplifier configurations which only require a single switch stage.

### PRIOR ART

There is a fundamental requirement to reduce or eliminate the inherent cost of the audio amplifier power supply. While a lot of work has been done to reduce the size and improve the efficiency of the power supply, there have also been several approaches to eliminate the power supply. The simplest way to eliminate the power supply is to simply rectify the unregulated AC mains voltage by using a bridge rectifier. Such rectified voltage, however, includes hum, noise and voltage fluctuations thus generally rendering such voltage useless to directly power an audio amplifier. Prior art has provided means to minimize the impact of such voltage fluctuations on the audio signal. Such means typically either filter the rectified voltage to reduce the voltage noise and hum or derive reference signals from the rectified voltage which are supplied to the amplifier in order to compensate for the fluctuations. These methods, however, are usually not able to fully eliminate the noise and hum and require additional components thus raising system cost. U.S. Pub. No. 2006/0244522 describes an approach to eliminate the impact of the voltage fluctuations on the audio signal. This method uses multipliers which are non-linear in nature thus causing audio distortion.

Prior art has further failed to address the issue that safety standards require galvanic isolation of all accessible conducting parts from the mains voltage which is normally provided by the dielectric insulation of the primary and secondary winding of the power supply transformer.

### OBJECTIVES

The main objective of the present invention is to provide a solution for an active loudspeaker which is able to eliminate power supply and thereby reduce the system cost and weight as well as the energy losses which are normally associated with a power supply.

Another objective of the invention is to provide a solution for an active speaker audio amplifier which offers similar audio quality as conventional linear class A amplifiers while at the same time providing the power efficiency of digital class D amplifiers.

Another objective of the invention is to provide a solution which reduces the amount of required power switching stages to reduce system cost.

The final objective of the invention is to offer a solution which provides for galvanic voltage isolation in order to comply with safety regulations.

### SUMMARY OF THE INVENTION

The above objectives are achieved with the present invention. In the preferred embodiment, a self-oscillating pulse modulation switching amplifier is used where the power switch stage is supplied a rectified non-stabilized mains voltage. The power-switched signal is voltage-divided and fed back to the pulse modulator which is part of the amplifier whereby the amplifier is able to remove voltage noise and fluctuations of the rectified voltage. The power-switched signal is low-pass filtered and drives a high-impedance speaker element in a half-bridge configuration. The audio signal is coupled from the audio input into the amplifier by an input stage which provides galvanic voltage isolation in compliance with safety regulations. The low-voltage portion of the amplifier is powered by a voltage rectifier which is capacitively coupled to the mains AC voltage.

### BRIEF DESCRIPTION OF THE DRAWINGS

The invention will be further described with reference to the drawings, in which,

FIG. 1 shows the principle in prior-art active speakers employing switching power amplifiers;

FIG. 2 shows a block diagram of a first embodiment of the invention;

FIG. 3 shows a block diagram of the pulse modulator of the amplifier;

FIG. 4 shows the signals of the pulse modulator;

FIG. 5 shows the audio input stage of the amplifier;

FIG. 6 shows the low-voltage power supply of the amplifier;

FIG. 7 shows the voltages of the low-voltage power supply;

FIG. 8 shows a block diagram of another embodiment which uses two speaker elements which are driven by two separate amplifier branches;

FIG. 9 shows a block diagram of another embodiment which uses a receiver to wirelessly receive the audio signal;

FIG. 10 shows a block diagram of another embodiment which uses a powerline receiver to receive the audio signal through the mains voltage.

### DETAILED DESCRIPTION OF THE PREFERRED EMBODIMENTS

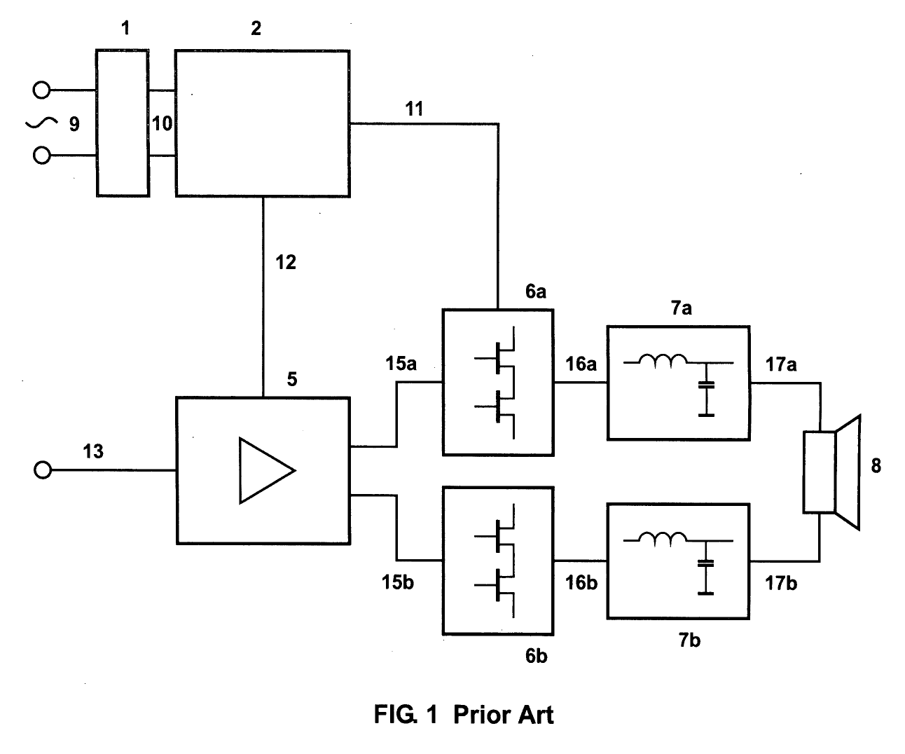

A typical prior-art active speaker with medium to high output power is shown in FIG. 1. A mains line filter 1 is filtering the mains voltage 9 in order to reduce noise and voltage spikes of the mains voltage and to attenuate switching noise conducted from the input voltage 10 of the switched-mode power supply 2 back to the mains voltage in order to comply with conducted power line emission regulations. The switched-mode power supply provides a low voltage/low current supply 12 for the amplifier pulse modulator 5 as well as a medium voltage/high current supply 11 for the amplifier power switching stages 6a and 6b. The amplifier pulse modulator converts the analog audio input signal 13 into two pulse-width modulated switch signals 15a and 15b which drive the power switching stages. The power-switched signals 16a and 16b are low-pass filtered by filters 7a and 7b. The filtered signals 17a and 17b drive a speaker element 8. The amplifier is configured in a full-bridge configuration in order to provide sufficient power to the speaker.

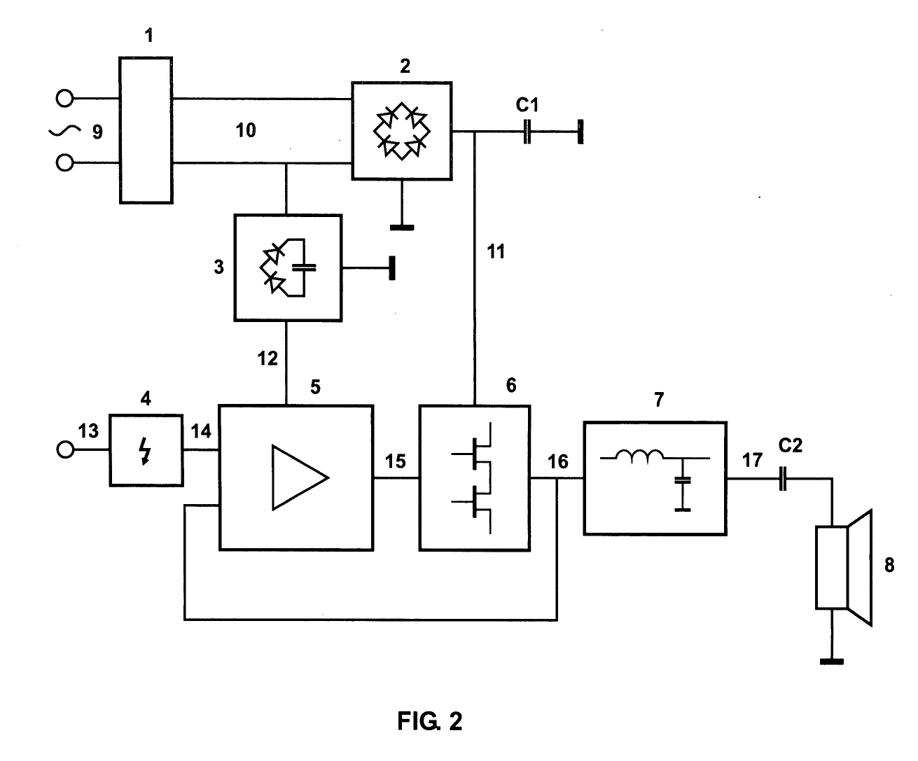

FIG. 2 illustrates the first embodiment of the invention. The mains voltage 9 is filtered by a mains line filter 1. The resulting voltage 10 is rectified by a bridge rectifier 2 and decoupled by capacitor C1. The rectified voltage 11 powers the amplifier power switching stage 6. A low-voltage power supply 3 generates a low voltage supply 12 for the amplifier pulse modulator 5. The analog audio input signal 13 is decoupled from the pulse modulator input voltage 14 by input stage 4. The modulator switch signal 15 drives a power switch stage 6. The power-switched signal 16 is low-pass filtered by filter 7 and drives a high-impedance speaker element 8 via decoupling capacitor C2. The power-switched signal is also fed back to a second input of the pulse modulator.

By using a feedback signal, the pulse modulator is able to ensure that any fluctuations and noise of the rectified mains voltage do not affect the audio signal quality. The modulator works as part of a control loop and thus corrects for any changes of the rectified voltage. Prior-art Class-D amplifiers aside from requiring a very stable supply voltage, have stringent requirements regarding the linearity of the pulse modulator as well as the component selection of the power switching stage as well as the switch dead time in order to minimize harmonic distortion of the amplified audio signal. Such switch dead time is the delay between the positive and negative switch element of the power switching stage to reduce shoot-through current and thereby improve power efficiency. In the present embodiment, the component selection is far more relaxed and an appropriate switch dead time can be chosen without a large trade off in terms of audio distortion. Since the rectified mains voltage which is supplying the power switching stage is in the order of 150 Volts to 300 Volts which is far higher than the supply voltage of prior-art amplifiers, the amplifier can achieve sufficient high output power in a half-bridge configuration. This results in a reduction in cost compared to prior-art amplifiers since only a single power switching stage and lower-pass filter are needed. While prior-art active speakers use speaker elements with speaker impedances of typically 4 to 8 Ohms, the speaker impedance of this embodiment would be in the order of 10 to 200 Ohms, depending on the output power requirement and mains supply voltage. By using a high-impedance speaker element, the cables connecting the speaker element with the amplifier can be fairly thin since the maximum speaker current is far lower than in prior-art speakers which typically use fairly thick and costly cables. A further advantage is that by using only a single power switching stage as opposed to two power switching stages in a full-bridge configuration, any possible intermodulation noise is avoided. Such intermodulation noise occurs when two or more power switching stages which operate from the same power supply run at different switching frequencies. Such intermodulation noise occurs at frequencies which are a multiple of the difference of the switching frequencies and can easily extend to the audible frequency band. Thereby the present embodiment is able to achieve a very high signal-to-noise ratio and has far less stringent requirements regarding the decoupling of the switching stage power supply voltage than prior-art active speakers.

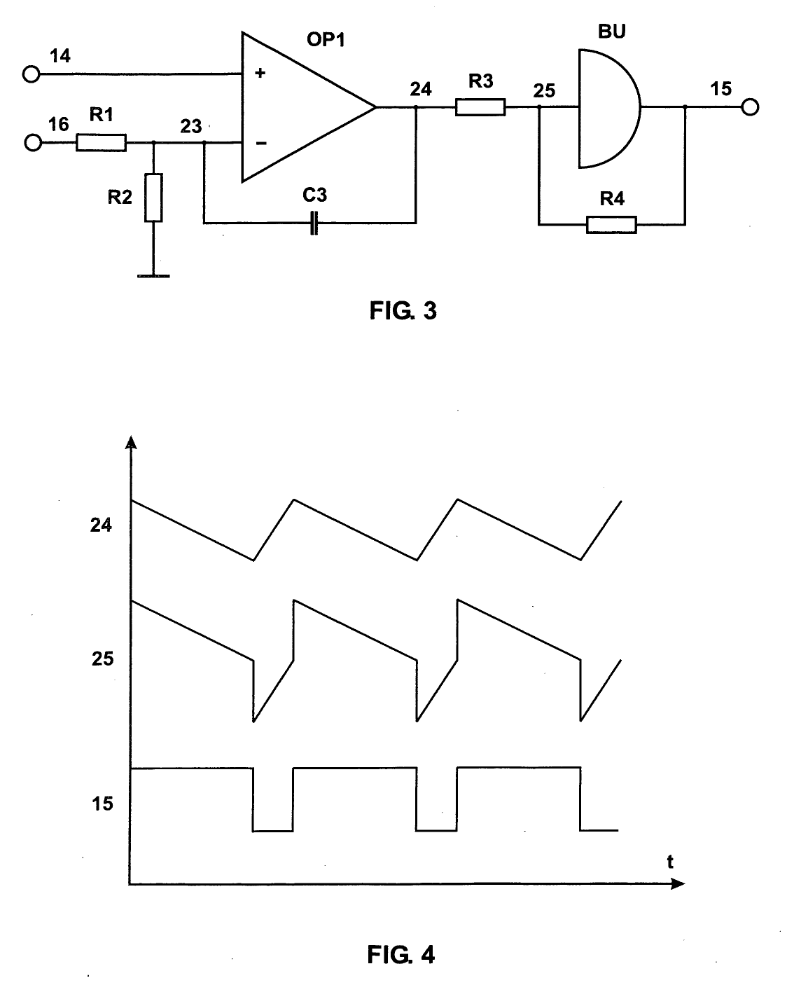

FIG. 3 shows the pulse modulator of the amplifier. The principle of such self-oscillating pulse modulator can be found in the prior art, such as U.S. Pat. No. 4,021,745. The input audio signal 14 is compared with a reference signal 16 which is the feedback signal from the power switching stage that is voltage divided by resistors R1 and R2. The difference is integrated by an operational amplifier OP1 and capacitor C3. The integrated signal 24 is input to a hysteresis comparator, formed by a non-inverting logic buffer BU and resistors R3 and R4. The output signal 15 of the buffer is driving the power switching stage.

FIG. 4 shows the signals of the pulse modulator. The signal numbers correspond to the numbers in FIG. 3. In the diagram, a situation is shown where the audio input signal 14 is positive. As a result, the falling slope of the integrated signal 24 is less steep than the rising slope. Therefore, the output signal 15 has a positive DC value and thus the output of the amplifier is positive.

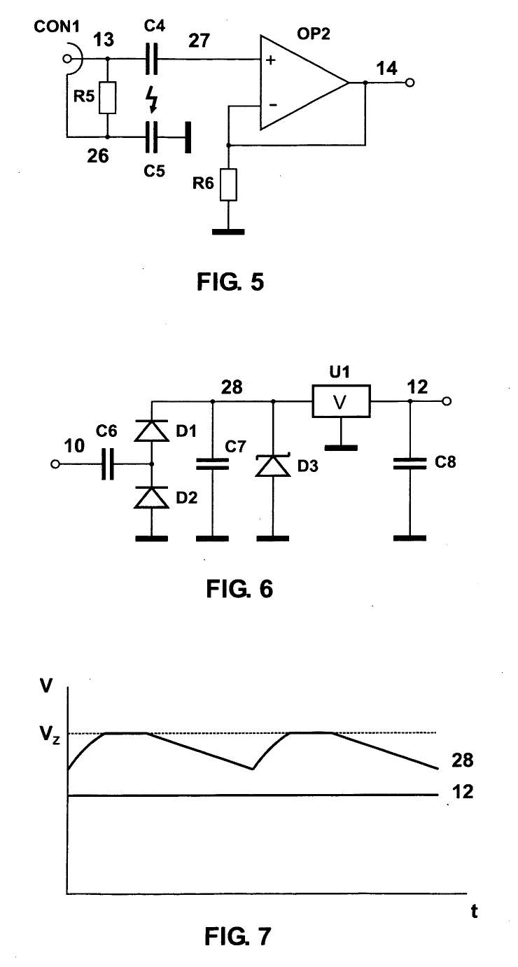

FIG. 5 shows the input coupling stage of the active speaker. Safety regulations typically require that all accessible conductive parts of a product be galvanically isolated from the power mains line. Magnetic coupling via a power transformer as well as capacitive coupling via capacitors are allowed. Such isolation must be designed such that the insulation can withstand high electric voltage surges, typically exceeding 1000 Volts. Prior-art active speakers achieve this objective by using a power supply where the secondary windings are insulated from the primary winding and the insulation of such power supply is designed to provide sufficient dielectric strength to withstand these high voltages. The input stage shown in FIG. 5 achieves compliance with safety regulations of the present invention without requiring a power supply with galvanically isolated windings. The audio input signal 13 is received by an unbalanced audio connector CON1. Resistor R5 presents the desired audio input impedance, typically in the order of 10 kOhms. The audio signal 13 and the audio signal ground 26 are coupled by capacitors C4 and C5. Capacitors C4 and C5 are chosen to be able to withstand a high voltage, typically in the order of 2000 Volts. Selecting input coupling capacitors with values found in prior-art active speakers, typically in the order of 10 uF to 100 uF, would be cost prohibitive at the required rated voltage. Therefore, the audio signal 27 following the coupling capacitor is connected to a high-impedance input of an operational amplifier OP2. The function of the operational amplifier is to transform the impedance of the audio signal input and provide a low impedance output audio signal 14 which is available for volume regulation, audio equalization and other stages following the input stage. By providing a high-impedance input, coupling capacitors C4 and C5 can be chosen to have a far lower value thereby allowing a cost effective solution. Due to the low value of the input coupling capacitors, an operational amplifier with little flicker noise should be chosen in order to achieve the desired signal-to-noise ratio at low frequencies.

In another embodiment of the invention, the audio output signal is connected to the pulse modulator directly without optional audio processing stages. In this embodiment, the operational amplifier of the input stage can be eliminated since the pulse modulator shown in FIG. 3 itself provides a high-impedance input and the input stage solely consists of input resistor R5 and input coupling capacitors C4, C5 thus yielding a very cost-effective solution. In this embodiment, it is further suggested that in FIG. 3 the resistors R1 and R2 be variable in order to allow changing the gain of the amplifier, effectively controlling the volume of the output signal since the input stage does not provide this functionality. Changing resistors R1 and R2 is easily done by a standard potentiometer. Since in the present invention, only a single power switching stage is used, a mono potentiometer is sufficient. While prior-art active speakers control the audio volume prior to the pulse modulator, changing the gain of the pulse modulator further offers the advantage that high signal-to-noise ratio is achieved even at small output volume. This behavior is especially important for active speakers offering a high maximum output power since noise would otherwise be noticeable at low audio volume.

In a further embodiment of the invention, instead of the input stage shown in FIG. 5, an audio transformer is used. Audio transformers are commonly used to galvanically isolate audio inputs and outputs from the remaining circuitry. In this embodiment, the insulation between the primary and secondary winding of such audio transformer must be designed to provide sufficient dielectric strength in order to withstand the voltage required by safety regulations, typically in excess of 1000 Volts.

FIG. 6 shows the low-voltage power supply which is supplying the power to the input stage and pulse modulator of the amplifier. The input is connected to an AC mains line 10 and coupled via capacitor C6 to rectifier diodes D1 and D2. The rectified voltage 28 is decoupled by capacitor C7 and voltage-limited by a Zener diode D3. Voltage regulator U1 generates a stabilized voltage supply 12 which is decoupled by capacitor C8. The ground of the low-voltage power supply is connected to the system ground which available from the mains line bridge rectifier 2 in FIG. 2.

This low-voltage power supply offers the advantage that no inductor, no high-voltage switching transistor, nor a step-down voltage regulator are required. These components would be necessary in a typical DC-DC step-down converter circuit. At the same time, this circuit offers the same efficiency as a DC-DC step-down converter circuit. It is crucial to select the value of coupling capacitor C6 according to the current requirement of the input stage and pulse modulator circuits. Capacitor C6 ensures that during every AC power cycle, a specified current charge is fed into decoupling capacitor C7 which is sufficient to supply power to the input stage and pulse modulator circuits during every AC power cycle.

FIG. 7 further illustrates the operating principle of the low-voltage power supply. During the rising edge of the AC mains power cycle, the rectified voltage 28 will rise to the maximum voltage Vz allowed by Zener diode D3. At the falling edge of the AC mains power cycle, the rectified voltage will start dropping as power is consumed. Capacitors C6, C7 and C8 must be selected such that the minimum of the rectified voltage during each power cycle will be higher than the stabilized supply voltage 12 plus the voltage differential required by voltage regulator U1. Diode D3 limits the rectified voltage to protect voltage regulator U1. Since coupling capacitor C6 itself is a pure capacitive load, the only energy losses are caused by the rectifying diodes D1, D2 and the voltage regulator U1. Therefore this circuit offers a high power efficiency and except for coupling capacitor C1 does not require any high-voltage components which would be necessary in a typical DC-DC step-down converter circuit.

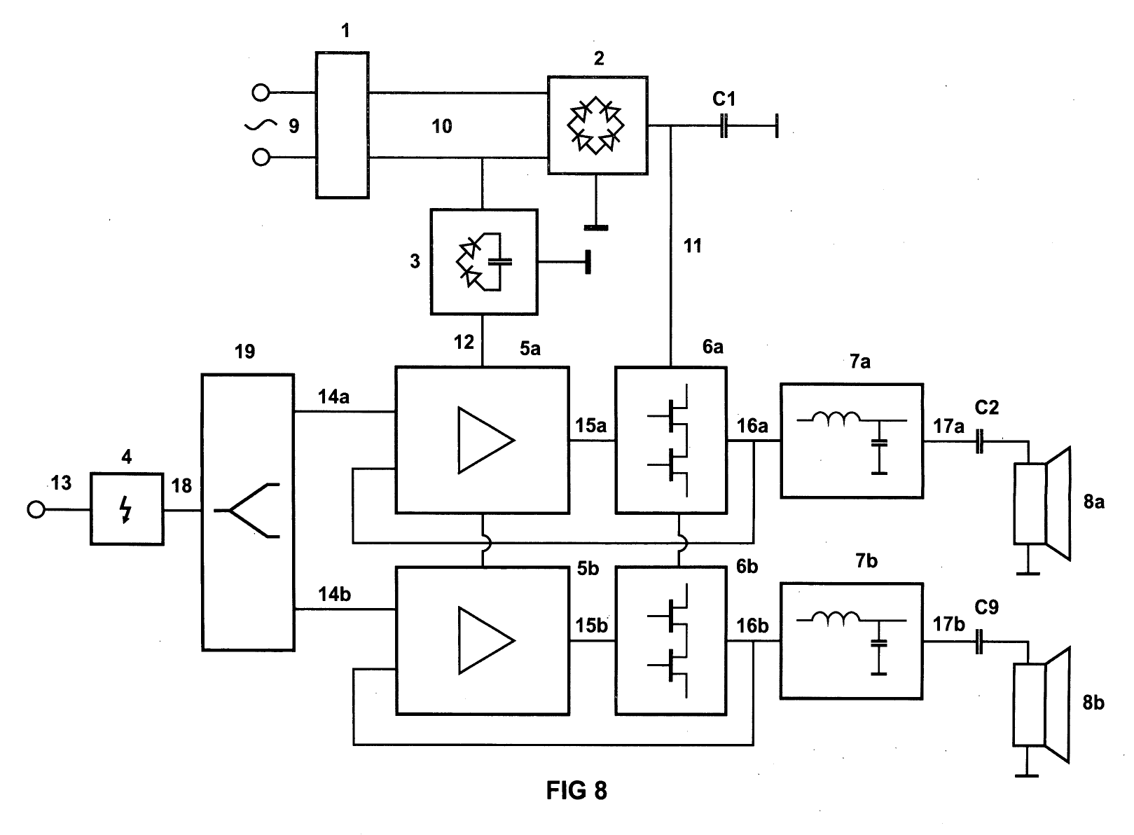

FIG. 8 shows another embodiment of the invention which utilizes two separate amplifier branches to drive two speaker elements. Typically this embodiment is used in an active speaker which has several speakers for different frequency bands. In this embodiment, the audio signal 18 is split into two frequency components 14a and 14b by frequency splitter 19 and input to pulse modulators 5a and 5b. The modulator switch signals 15a and 15b drive power switch stages 6a and 6b respectively. The power-switched signals 16a and 16b are low-pass filtered by filters 7a and 7b and drive two high-impedance speaker elements 8a and 8b via decoupling capacitors C2 and C9 respectively. In this embodiment, the cut-off frequency of the low-pass filters should be selected based on the frequency of the speaker elements. Further, the switch frequency of the low-audio-frequency branch should be selected to be lower than the switch frequency of the medium-audio-frequency branch. This offers the following advantages compared to prior-art active speakers: If the switching frequencies of both path are different, the frequency of intermodulation noise components will be fairly high and thus outside of the audible frequency band. Further, the capacitive energy losses are reduced as the switching frequency is reduced. Also, dead-times of the switching stage will cause less distortion as the switching frequency is reduced and thus the energy efficiency can be further increased by raising the switching dead times.

In a further embodiment of the invention, an equalizer is added prior to the pulse modulator which is modeled after the speaker element in order to yield a desired frequency response of the active speaker. Such equalizer will help reduce the demands of the speaker design and also allow selection of less costly speaker elements by compensating for the inferior frequency or phase response of the speaker element. Said equalizer can be designed to be controllable, so that for example the bass or treble of the active speaker can be adjusted. It is obvious for the skilled in the art that additional elements can be incorporated, such as a volume control or a mute-mechanism to set the pulse modulator into standby mode when no audio signal is received.

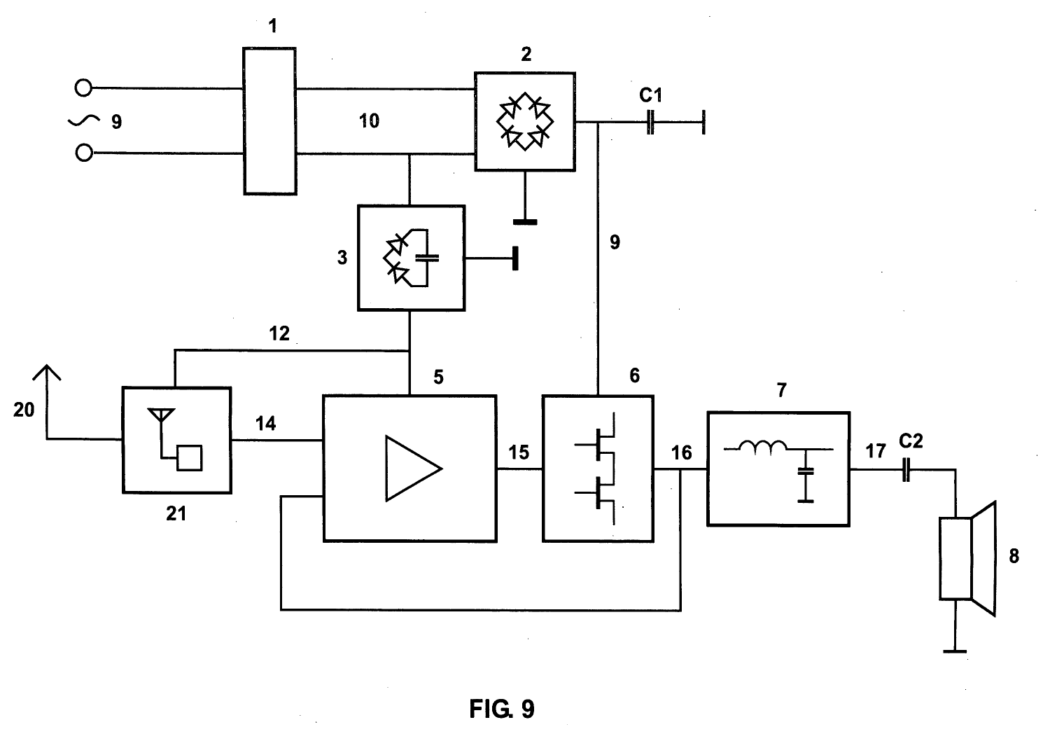

FIG. 9 shows another embodiment of the invention in which the speaker receives a wireless audio signal 20. The audio output signal 14 of wireless receiver 21 is input to the pulse modulator. The wireless receiver may be a radio-frequency receiver or an optical (e.g. infrared) receiver. If the wireless receiver is a digital receiver, it includes a digital-to-analog converter to convert the received digital signal into the analog audio signal 14 which is input to the pulse modulator.

Since in this embodiment there are no user-accessible audio inputs, no input stages or transformers are required in order to comply with safety regulations.

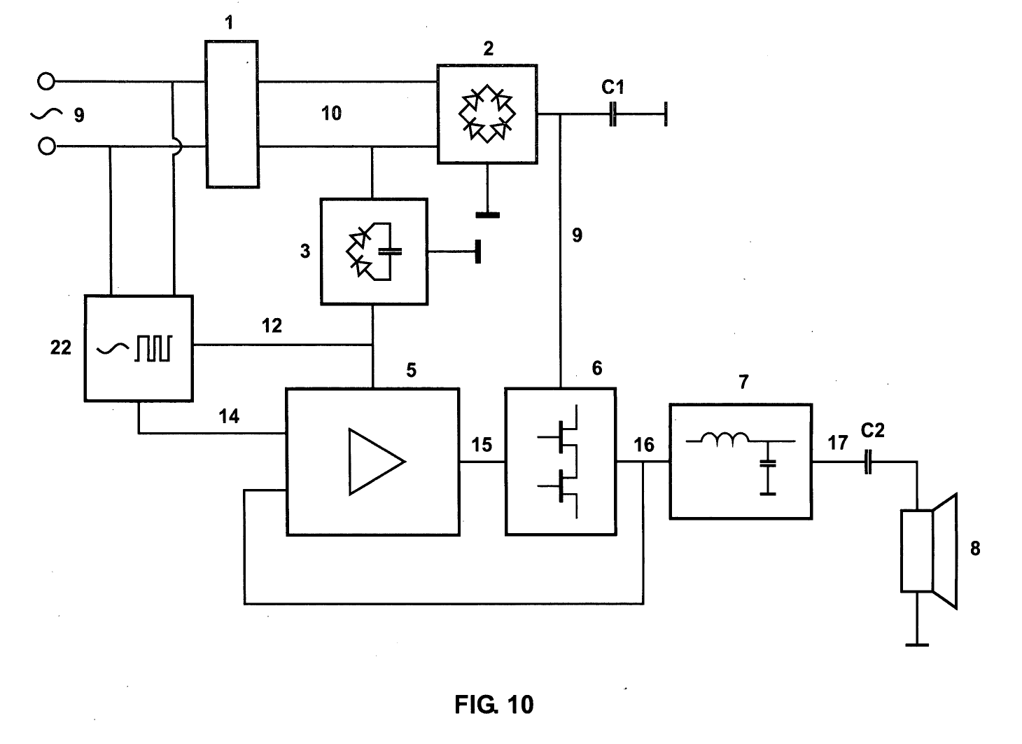

FIG. 10 shows a further embodiment of the invention. The speaker receives the audio signal via the mains power line by a powerline receiver 22. Such powerline audio data signal is typically modulated as an OFDM (orthogonal-frequency-division-multiplex) carrier in the frequency range of several MHz onto the mains power line and typically offers a higher transmit range than the wireless embodiment shown in FIG. 9. The powerline receiver includes a coupling element to couple onto the AC mains signal 9 as well as a demodulator to receive and demodulate the audio data and a digital-to-analog converter to convert the audio data to an analog audio signal 14 which is input to the pulse modulator. The powerline receiver should be coupled onto the AC mains line prior to the mains line filter 1 to avoid degradation of the powerline data signal by the mains line filter.

It is obvious that various aspects of one of the described embodiments can be incorporated in or combined with another embodiment of the invention.

Further, this invention is not limited to stand-alone active speakers but can be applied to a wide range of audio and video appliances.

In a further embodiment of the invention, the active speaker is part of an integrated radio receiver and CD player device. In this embodiment, the size of the power supply can be reduced since it does not have to provide power to the speaker audio amplifier. Thus the cost and weight of the audio appliance in this embodiment can be reduced.

In another embodiment, the active speaker is part of a television set with integrated loudspeakers.

Further variants and applications of the invention can be derived from the above descriptions by the skilled in the art.

What is claimed is:

1. An apparatus for amplifying and reproducing an audio signal, comprising:
rectifying means for generating an unregulated DC voltage from the AC mains voltage;
pulse modulator means including integrating means for integrating the difference between an audio input signal and at least one reference signal which is derived from a component following the pulse modulator means and hysteresis buffer means for generating a pulse-modulated switch signal from the integrated difference signal;
power switching means for switching said unregulated DC voltage according to said switch signal;
filter means for low-pass filtering the switched signal of the power switching means; and
audio reproducing means for outputting the low-pass filtered signal of the filter means as a sound wave.

2. An apparatus according to claim 1, further comprising input coupling means, including an input resistor which is connected between the external audio input and the audio-input ground; a first high-voltage capacitor with a rated voltage of at least 1000 Volts which is connected between the external audio input and the internal audio input; and a second high-voltage capacitor which is connected between the external audio ground and the internal audio ground.

3. An apparatus according to claim 1, further comprising input coupling means, including audio transformer means which offer a primary and a secondary winding, wherein both windings are electrically isolated from each other and the isolating material between the windings offers a dielectric strength of at least 1000 Volts.

4. An apparatus according to claim 1, wherein at least one reference signal which is fed back to the pulse modulating means is generated by a voltage divider which includes at least one adjustable resistor.

5. An apparatus according to claim 1, wherein a speaker element with an impedance of 8 Ohms or greater is used for the audio reproducing means.

6. An apparatus according to claim 1, wherein the pulse modulating means are preceded by audio equalizing means which change the frequency response of the audio signal which is input to the pulse modulating means.

7. An apparatus according to claim 6, wherein the frequency response of the equalizing means is adjustable.

8. An apparatus according to claim 1, further comprising a rectified low-voltage power supply, including:
two diodes and a decoupling capacitor, forming a half-bridge voltage rectifier for generating a rectified voltage;
a capacitor with a rated voltage of at least 100 Volts which is connected between one of the AC mains voltage lines and the connection between said two diodes;
a Zener diode which is connected between said rectified voltage and ground; and
a fixed voltage regulator—the input of which is connected to said rectified voltage.

9. An apparatus according to claim 1, further comprising:
frequency filter means for separating the audio input audio signal into at least two frequency components and inputting one of said frequency components into the pulse modulating means;
at least one additional amplifier branch, each of which is input one of said frequency components, including:
additional pulse modulator means; additional power switching means; additional filter means; and additional audio reproducing means.

10. An apparatus according to claim 9, wherein the switch frequency and the cut-off frequency of the filter means in separate amplifier branches are different and the frequency difference is at least 20 kHz.

11. An apparatus according to claim 1, further comprising:
wireless receiver means for receiving the audio signal from transmitter means via radio waves or light waves.

12. An apparatus according to claim 1, further comprising:
powerline receiver means for receiving the audio signal from transmitter means via the mains power line.

13. An apparatus according to claim 11 or 12, wherein the receiver means further receive control information from transmitter means which is used to adjust the behavior of the apparatus.

14. An apparatus according to claim 1, wherein the apparatus is part of an audio appliance with integrated speakers which comprises additional means for generation of the audio signal.

15. An apparatus according to claim 1, wherein the apparatus is part of a video appliance with integrated speakers which comprises additional means for displaying a video signal.
